(19) United States
(12) Patent Application Publication
(10) Pub. No.: US 2025/0167438 A1
(43) Pub. Date: May 22, 2025

(54) CONDUCTIVE MEMBER, HEATER, AND LIGHT CONTROL CELL

(71) Applicant: FUJIFILM Corporation, Tokyo (JP)

(72) Inventors: Takao TAGUCHI, Kanagawa (JP); Takahiko ICHIKI, Kanagawa (JP)

(73) Assignee: FUJIFILM Corporation, Tokyo (JP)

(21) Appl. No.: 19/027,108

(22) Filed: Jan. 17, 2025

Related U.S. Application Data
(63) Continuation of application No. PCT/JP2023/025713, filed on Jul. 12, 2023.

(30) Foreign Application Priority Data
Jul. 29, 2022 (JP) 2022-121665

(51) Int. Cl. H01Q 1/42; B60Q 1/50; H05B 3/84

(52) U.S. Cl. CPC H01Q 1/42; B60Q 1/50; H05B 3/84; H05B 2203/013

(57) ABSTRACT

A conductive member includes a mesh-shaped portion (14) that includes a plurality of meshes (14A) formed of a plurality of conductive wirings (21a) extending along two directions, in which the plurality of conductive wirings (21A) are arranged by wiring pitches C in two arrangement directions, the mesh-shaped portion (14) includes a plurality of non-conductive portions (22), the non-conductive portion (22) includes at least one extension portion (E1, E2), the extension portion (E1, E2) extends along one direction among the two directions, and a width A of the extension portion (E1, E2) in an orthogonal direction orthogonal to the one direction, a gap B in the orthogonal direction between the conductive wiring (21A) and the extension portion (E1, E2) adjacent to each other in the orthogonal direction, and the wiring pitch C of the plurality of conductive wirings satisfy a relational expression of A<B<C.

### CROSS-REFERENCE TO RELATED APPLICATIONS

This application is a Continuation of PCT International Application No. PCT/JP2023/025713 filed on Jul. 12, 2023, which claims priority under 35 U.S.C. § 119 (a) to Japanese Patent Application No. 2022-121665 filed on Jul. 29, 2022. The above applications are hereby expressly incorporated by reference, in their entirety, into the present application.

### BACKGROUND OF THE INVENTION

### 1. Field of the Invention

The present invention relates to a conductive member having transmittance with respect to an electromagnetic wave in a specific frequency band, a heater, and a light control cell.

### 2. Description of the Related Art

In the related art, a sensor, a communication apparatus, or the like using an electromagnetic wave such as a millimeter wave or a microwave is generally used. This apparatus is mounted on, for example, an automobile, and a protective cover is provided around the apparatus in many cases. It is known that snow accretion or ice accretion on the cover or fogging or the like caused by water vapor causes erroneous detection in the sensor or communication failure in the communication apparatus disposed inside the cover. In order to remove snow accretion, ice accretion, and fogging, for example, a conductive member disclosed in JP2016-143914A is developed. The conductive member of JP2016-143914A includes a mesh consisting of a plurality of conductive wirings, and functions as a heater by energizing the mesh.

In addition, it is known that an electromagnetic wave in a frequency band different from the frequency band of the electromagnetic wave that is transmitted and received by the sensor, the communication apparatus, or the like causes erroneous detection in the sensor and communication crosstalk or the like in the communication apparatus. In order to suppress erroneous detection in the sensor and communication crosstalk or the like, for example, a radome disclosed in JP2006-258449A is developed. The radome of JP2006-258449A includes a frequency selective layer where non-conductive portions consisting of cross-shaped openings are formed on a conductor plate. Due to the plurality of non-conductive portions, an electromagnetic wave in a frequency band corresponding to the size of the cross shape is likely to transmit the frequency selective layer, and an electromagnetic wave in the other frequency band is shielded.

### SUMMARY OF THE INVENTION

Incidentally, in order to obtain a conductive member having a function as a heater and a function of selectively allowing transmission of an electromagnetic wave in a specific frequency band, for example, in a case where the non-conductive portions disclosed in JP2006-258449A are formed on the mesh consisting of the plurality of conductive wirings disclosed in JP2016-143914A, the plurality of conductive wirings forming the mesh may be conspicuous and visible due to the plurality of non-conductive portions formed on the mesh. This way, in a case where the plurality of conductive wirings forming the mesh are conspicuous and visible, in a case where a member of which the design is desired to be visible to an external observer, for example, an emblem of an automobile is covered, the design of the member may deteriorate.

The present invention has been made in order to solve the above-described problems, and an object thereof is to provide a conductive member where conductive wirings are inconspicuous while simultaneously achieving a heat generation function and a function of allowing transmission of an electromagnetic wave in a specific frequency band, a heater, and a light control cell.

The above object can be achieved by the following configuration.

[1] A conductive member comprising:
a substrate; and
a mesh-shaped portion that includes a plurality of meshes formed of a plurality of conductive wirings disposed on the substrate and extending along two directions intersecting each other,
in which the plurality of conductive wirings are arranged at regular intervals by respectively determined wiring pitches in two arrangement directions orthogonal to the two directions, respectively,
the mesh-shaped portion includes a plurality of non-conductive portions that are arranged to form a regular repeating pattern and each of which is trimmed by the continuous conductive wiring,
the non-conductive portion includes at least one extension portion,
the extension portion extends along one direction among the two directions, and
a width A of the extension portion in an orthogonal direction orthogonal to the one direction, a gap B in the orthogonal direction between the extension portion and the conductive wiring that extends along the one direction and is adjacent to the extension portion in the orthogonal direction, and the wiring pitch C of the plurality of conductive wirings in the orthogonal direction satisfy a relational expression of A<B<C.

[2] The conductive member according to [1],
in which the width A, the gap B, and the wiring pitch C satisfy a relational expression of A>0.3B>0.16C.

[3] The conductive member according to [1] or [2],
in which the two directions are orthogonal to each other,
the non-conductive portion includes a pair of the extension portions extending along the two directions, respectively, and intersecting each other, and
each of the pair of extension portions satisfies the relational expression.

[4] The conductive member according to [3],
in which the non-conductive portion has a shape where a pair of rectangles having the same shape and size are orthogonal to each other.

[5] The conductive member according to [1] or [2],
in which the extension portion has a shape of a rectangle having a long side along the one direction.

[6] The conductive member according to [5],
in which the extension portion is disposed such that a center line along the long side of the rectangle is positioned on the same straight line with respect to the conductive wiring forming the mesh.

[7] The conductive member according to any one of [1] to [6],
in which a length L of the extension portion in the one direction satisfies K/4≤L≤K/2 with respect to a wavelength K of an electromagnetic wave transmitted through the non-conductive portion.

[8] The conductive member according to any one of [1] to [7],
in which the width A of the extension portion satisfies 0.04L≤A≤0.3L with respect to a length L of the extension portion in the one direction.

[9] The conductive member according to any one of [1] to [8],
in which a centroid-to-centroid distance H of the two non-conductive portions adjacent to each other satisfies 1.3L≤H≤2.7L with respect to a length L of the extension portion in the one direction.

[10] A heater comprising:
the conductive member according to any one of [1] to [9].

[11] A light control cell comprising:
the conductive member according to any one of [1] to [9].

The conductive member according to the aspect of the present invention includes: a substrate; a mesh-shaped portion that includes a plurality of meshes formed of a plurality of conductive wirings disposed on the substrate and extending along two directions intersecting each other, in which the plurality of conductive wirings are arranged at regular intervals by respectively determined wiring pitches in two arrangement directions orthogonal to the two directions, respectively, the mesh-shaped portion includes a plurality of non-conductive portions that are arranged to form a regular repeating pattern and each of which is trimmed by the continuous conductive wiring, the non-conductive portion includes at least one extension portion, the extension portion extends along one direction among the two directions, and a width A of the extension portion in an orthogonal direction orthogonal to the one direction, a gap B in the orthogonal direction between the extension portion and the conductive wiring that extends along the one direction and is adjacent to the extension portion in the orthogonal direction, and the wiring pitch C of the plurality of conductive wirings in the orthogonal direction satisfy a relational expression of A<B<C. Therefore, the conductive wirings are inconspicuous while simultaneously achieving a heat generation function and a function of allowing transmission of an electromagnetic wave in a specific frequency band.

### BRIEF DESCRIPTION OF THE DRAWINGS

FIG. 1 is a cross sectional view schematically showing a part of a conductive member according to an embodiment of the present invention.

FIG. 2 is a plan view showing the conductive member according to the embodiment of the present invention.

FIG. 3 is an enlarged schematic diagram showing a mesh according to the embodiment of the present invention.

FIG. 4 is an enlarged diagram showing a mesh-shaped portion according to the embodiment of the present invention.

FIG. 5 is a diagram showing two non-conductive portions adjacent to each other in the embodiment of the present invention.

FIG. 6 is an enlarged diagram showing a mesh-shaped portion according to a first modification example of the embodiment of the present invention.

FIG. 7 is a diagram showing a non-conductive portion according to a second modification example of the embodiment of the present invention.

FIG. 8 is a diagram showing a non-conductive portion according to a third modification example of the embodiment of the present invention.

FIG. 9 is an enlarged diagram showing a mesh-shaped portion according to a fourth modification example of the embodiment of the present invention.

FIG. 10 is an enlarged diagram showing a mesh-shaped portion according to a fifth modification example of the embodiment of the present invention.

FIG. 11 is an enlarged diagram showing a mesh-shaped portion according to a sixth modification example of the embodiment of the present invention.

### DESCRIPTION OF THE PREFERRED EMBODIMENTS

Hereinafter, a conductive member according to the present invention will be described in detail based on a preferred embodiment shown in the accompanying drawings.

The drawings described below are exemplary drawings for describing the present invention, and the present invention is not limited to the drawings described below.

In the following description, a numerical range indicated by the expression “to” includes numerical values described on both sides. For example, in a case where & is a numerical value a to a numerical value B, the range & is a range including the numerical value a and the numerical value B, which is expressed by a mathematical symbol α≤ε≤β.

Unless specified otherwise, the meaning of an angle such as “parallel” or “orthogonal” includes a case where an error range is generally allowable in the technical field.

In addition, the meaning of “the same” includes a case where an error range is generally allowable in the technical field.

In this specification, “(meth)acrylate” denotes either or both of acrylate and methacrylate, and “(meth)acryl” denotes either or both of acryl and methacryl. In addition, “(meth)acryloyl” denotes either or both of acryloyl and methacryloyl.

Unless specified otherwise, being transparent with respect to visible light represents that a visible light transmittance in a visible wavelength range of 380 nm to 800 nm is 40% or more, preferably 80.0% or more, and more preferably 90.0% or more. In the following description, unless specified otherwise, being transparent represents being transparent with respect to visible light.

The visible light transmittance is measured using “Plastics—Determination of Total Luminous Transmittance and Reflectance” defined by Japanese Industrial Standards (JIS) K 7375:2008.

### Embodiment

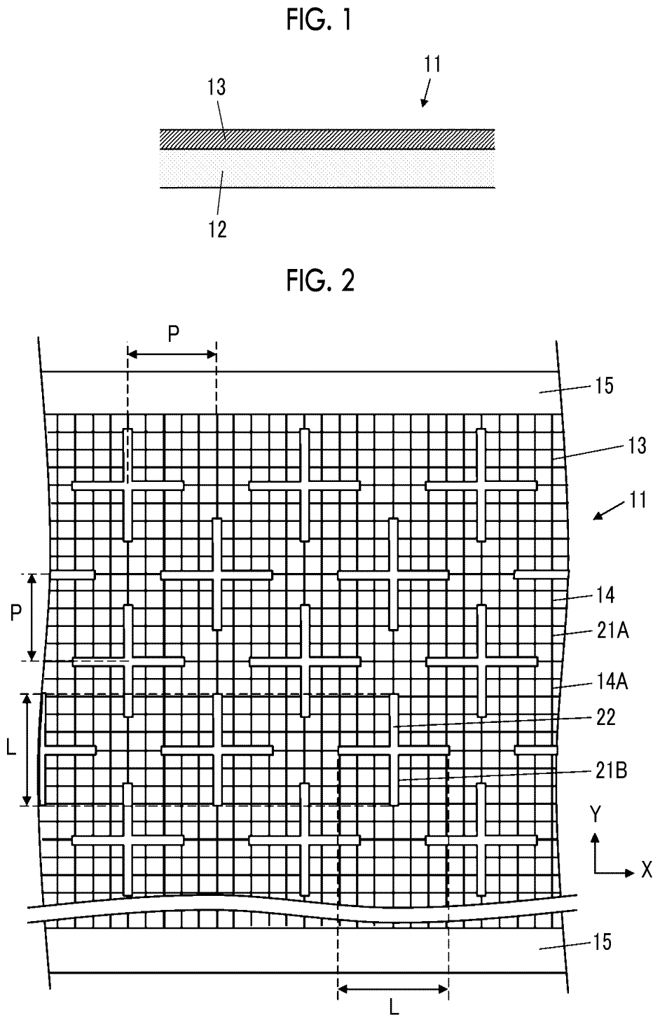

FIG. 1 is a conductive member 11 according to an embodiment of the present invention. The conductive member 11 is a film-like member and includes an insulating transparent substrate 12 and a conductive layer 13 that is formed on a single surface of the substrate 12.

The conductive layer 13 has a visible light transmittance of, for example, 75.0% or more.

As shown in FIG. 2, the conductive layer 13 of the conductive member 11 includes a mesh-shaped portion 14 and a pair of electrode pads 15 that are connected to both ends of the mesh-shaped portion 14 to apply a voltage to the mesh-shaped portion 14. The mesh-shaped portion 14 includes a plurality of meshes 14A formed of a plurality of conductive wirings 21A extending along two directions intersecting each other. Each of the pair of electrode pads 15 has a shape of a rectangle, has long side extending along one direction among two directions in which the plurality of conductive wirings 21A extend, and is disposed such that the long sides thereof face each other in the other direction. Here, for example, by applying a voltage to the pair of electrode pads 15 such that a current flows through the mesh-shaped portion 14, the mesh-shaped portion 14 can be heated. As a result, the conductive member 11 functions as a so-called heater.

Hereinafter, among the two directions in which the plurality of conductive wirings 21A extend, a direction in which the long sides of the pair of electrode pads 15 extend will be referred to as an X direction, and a direction orthogonal to the X direction and from one electrode pad 15 to the other electrode pad 15 will be referred to as a Y direction.

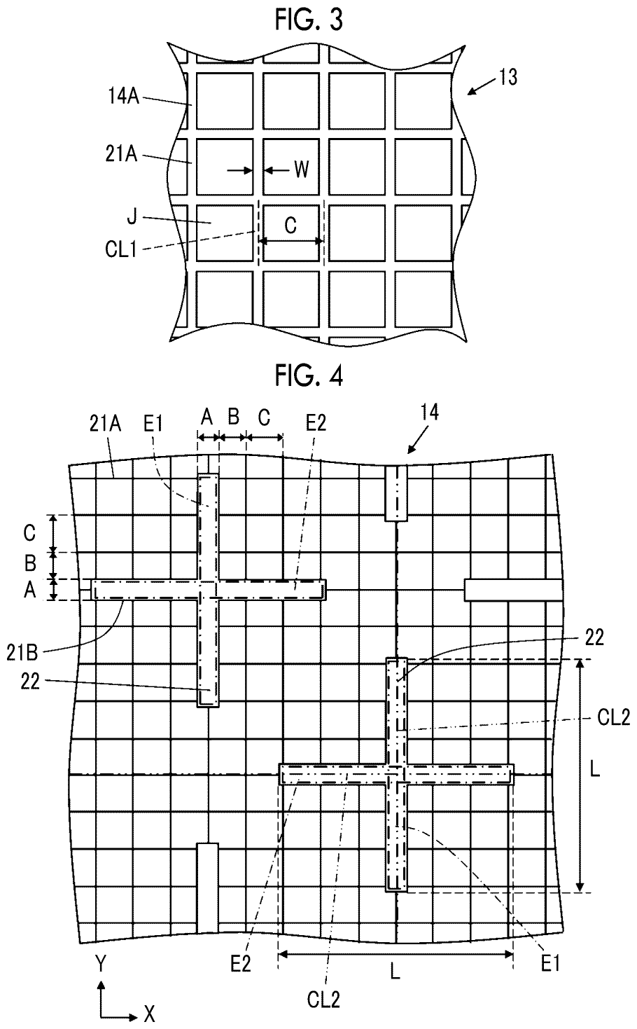

As shown in FIG. 3, the plurality of conductive wirings 21A forming the mesh 14A have a line width W and are disposed at a wiring pitch C defined as a distance between center lines CL1 of the conductive wirings 21A.

In addition, the mesh 14A includes a plurality of square opening portions J and forms a so-called square grid.

The line width W of the conductive wirings 21A is not particularly limited, and the upper limit thereof is preferably 1000.00 μm or less, more preferably 500.00 μm or less, and still more preferably 300.00 μm or less. The lower limit of the line width W is preferably 1.00 μm or more and more preferably 3.00 μm or more. In a case where the line width W is in the above-described range, the mesh 14A can be made to have a high conductivity. In addition, from the viewpoint of conductivity, the thickness of the conductive wirings 21A can be set to be 0.01 μm or more and 200.00 μm or less, and the upper limit thereof is preferably 30.00 μm or less, more preferably 20.00 μm or less, still more preferably 9.00 μm or less, and still more preferably 5.00 μm or less. The lower limit of the thickness of the conductive wirings 21A is preferably 0.01 μm or more, more preferably 0.10 μm or more, and still more preferably 0.5 μm or more.

A sheet resistance of the conductive layer 13 formed of the plurality of conductive wirings 21 is preferably 0.1Ω/□ or more and 10.0Ω/□ or less and more preferably 0.3Ω/□ or more and 3.0Ω/□ or less. This way, the conductive layer 13 has a low sheet resistance of 10.0Ω/□ or less. Therefore, the conductive layer 13 has a high heater performance of generating a large amount of heat under a condition where a voltage is limited, and has a high electromagnetic wave transmittance. In addition, the conductive layer 13 has a resistance value of 0.10Ω/□ or more. Therefore, the conductive layer 13 has a high heater performance of generating a large amount of heat under a condition where a current is limited.

In addition, as shown in FIG. 2, the mesh-shaped portion 14 includes a plurality of non-conductive portions 22 that are arranged to form a regular repeating pattern and are trimmed by a continuous conductive wiring 21B. The plurality of non-conductive portions 22 are alternately arranged such that two non-conductive portions 22 closest to each other are shifted at an arrangement pitch P in the X direction and the Y direction. Here, the arrangement pitch P can be defined by a distance in the X direction or the Y direction between centers of the two non-conductive portions 22 closest to each other.

As shown in FIG. 4, the non-conductive portion 22 is trimmed by the continuous conductive wiring 21B, and a conductive member is not present inside the continuous conductive wiring 21B.

In addition, the non-conductive portion 22 includes a rectangular extension portion E1 extending along the Y direction and a rectangular extension portion E2 extending along the X direction, and has a cross shape where the pair of extension portions E1 and E2 are formed to intersect each other. The extension portion E1 extending along the Y direction has a length L in the Y direction and has a width A in the X direction. In addition, the extension portion E2 extending along the X direction has a length L in the X direction and has a width A in the X direction. A center position of the extension portion E1 and a center position of the extension portion E2 match with each other. In addition, each of the pair of extension portions E1 and E2 is disposed such that a center line CL2 along the long side of the rectangle is positioned on the same straight line with respect to conductive wiring 21A forming the mesh 14A.

Here, the non-conductive portion 22 allows transmission of an electromagnetic wave in a specific frequency band corresponding to the length L and the width A of the extension portions E1 and E2. For example, in a case where an electromagnetic wave having the wavelength K as a central wavelength transmits through the non-conductive portion 22, it is preferable that the length L of the extension portions E1 and E2 is designed to satisfy K/4≤L≤K/2. In addition, it is preferable that the width A is designed to satisfy 0.04L≤A≤0.3L with respect to the length L. For example, in a case where an electromagnetic wave having a center frequency of 76.5 GHz called a millimeter wave transmits through the non-conductive portion 22, the length L can be designed to 1330 μm, and the width A can be designed to 120 μm. Note that it is preferable that the length L1 and the width A are appropriately adjusted because they also depend on a positional relationship between the plurality of non-conductive portions 22.

This way, the plurality of non-conductive portions 22 are formed in the mesh-shaped portion 14. Therefore, the mesh-shaped portion 14 allows transmission of an electromagnetic wave in a specific frequency band and shields an electromagnetic wave in the other frequency band.

Here, the width A of the extension portion E1 extending along the Y direction, a gap B in the X direction between the extension portion E1 and the conductive wiring 21A extending along the Y direction and adjacent to the extension portion E1 in the X direction, and the wiring pitch C of the plurality of conductive wirings 21A in the X direction satisfy a relationship of A<B<C. In addition, the width A of the extension portion E2 extending along the X direction, a gap B in the Y direction between the extension portion E2 and the conductive wiring 21A extending along the X direction and adjacent to the extension portion E2 in the Y direction, and the wiring pitch C of the plurality of conductive wirings 21A in the Y direction satisfy a relationship of A<B<C.

This way, in each of the X direction and the Y direction, the width A, the gap B, and the wiring pitch C satisfies the relationship of A<B<C, that is, the dimensions increase stepwise in order of the width A, the gap B, and the wiring pitch C a change in the dimensions of the width A, the gap B, and the wiring pitch C is not conspicuous to an observer who observes the mesh-shaped portion 14, and the conductive wirings 21A extending along the X direction and the Y direction and the conductive wiring 21B that trims the non-conductive portion 22 are inconspicuous.

Therefore, for example, in a case where the conductive member 11 according to the embodiment of the present invention covers a member of which the design is desired to be visible to an external observer, for example, an emblem of an automobile, deterioration in the design of the member can be prevented, which is useful.

As described above, in the conductive member 11 according to the embodiment of the present invention, since the width A, the gap B, and the wiring pitch C satisfies the relationship of A<B<C, the conductive wirings 21A and 21B are inconspicuous while simultaneously achieving a heat generation function and a function of allowing transmission of an electromagnetic wave in a specific frequency band.

In addition, although not shown in the drawing, a heater can be configured with the conductive member 11 according to the embodiment of the present invention and a power supply device for applying a voltage to the conductive layer 13 in the conductive member 11. This heater is particularly useful in a case where the heater is disposed to cover a sensor, a communication apparatus, or the like using an electromagnetic wave such as a so-called millimeter wave or a microwave that is provided in, for example, an automobile.

For example, in a case where snow accretion, ice accretion, or the like occurs around the sensor, the communication apparatus, or the like, it is known that erroneous detection in the sensor or communication failure in the communication apparatus is likely to occur. In addition, in a case where an electromagnetic wave in a frequency band different from an electromagnetic wave that is transmitted and received by the sensor, the communication apparatus, or the like is present around the sensor, the communication apparatus, or the like, it is also known that crosstalk between the electromagnetic waves in the different frequency bands occurs such that the erroneous detection or the communication failure is likely to occur.

With the heater including the conductive member 11 according to the embodiment of the present invention, snow accretion, ice accretion or the like caused by the heater can be removed, the transmission of the electromagnetic wave in the frequency band corresponding to the size of the plurality of non-conductive portions 22 in the conductive member 11 can be allowed, and an electromagnetic wave in the other frequency band can be shielded. Therefore, the effect of snow accretion, ice accretion, or the like can be suppressed, and erroneous detection, communication failure, or the like in the sensor, the communication apparatus, or the like can be suppressed. Further, since this heater includes the conductive member 11 according to the embodiment of the present invention and the width A, the gap B, and the wiring pitch C satisfies the relationship of A<B<C, the conductive wirings 21A and 21B are inconspicuous while simultaneously achieving a heat generation function and a function of allowing transmission of an electromagnetic wave in a specific frequency band.

In addition, although not shown in the drawing, a light control cell can also be configured with a pair of the conductive members 11, a liquid crystal layer that is disposed between the pair of conductive members 11, and a power supply device for applying a voltage to the pair of conductive members 11. The light control cell is disposed on window glass to adjust the amount of external light transmitted through the window glass. Since the width A, the gap B, and the wiring pitch C satisfies the relationship of A<B<C in the conductive member 11, the conductive wirings 21A and 21B can be made inconspicuous through the window glass. In addition, for example, a light control cell in the related art is likely to be configured with a transparent conductive material such as indium tin oxide (ITO). In this case, an electromagnetic wave cannot transmit through the light control cell. The light control cell according to the embodiment of the present invention can allow transmission of an electromagnetic wave. Therefore, for example, communication using the electromagnetic wave can be performed through the window glass where the light control cell is disposed. The light control cell can also include a transparent support film instead of one of the pair of conductive members 11.

The present inventors found that, in a case where the width A, the gap B, and the wiring pitch C satisfies the relationship of A<B<C and further satisfies a relational expression of A>0.3B>0.16C, the conductive wirings 21A and 21B can be made more inconspicuous. As a result, the conductive member 11 can make the conductive wirings 21A and 21B more inconspicuous while simultaneously achieving a heat generation function and a function of allowing transmission of an electromagnetic wave in a specific frequency band.

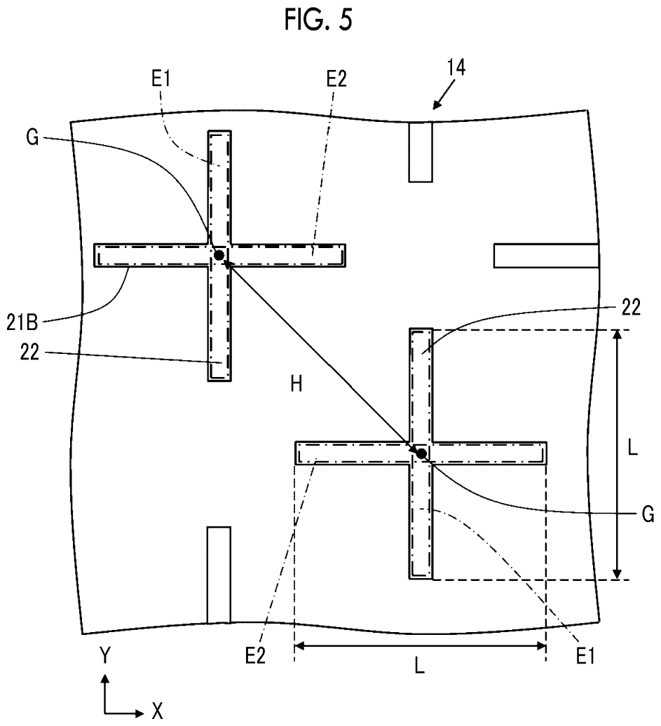

Incidentally, in the above description, the frequency band of the electromagnetic wave that selectively transmits through the conductive member 11 is determined depending on the dimensions of the non-conductive portions 22. Due to resonance between the plurality of non-conductive portions 22, a peak frequency in the frequency band, that is a frequency at which the amount of electromagnetic waves transmitted through the conductive member 11 is the maximum is generated. The peak frequency can be adjusted by adjusting a centroid-to-centroid distance H defined by the shortest distance between the centroids G of two non-conductive portions 22 adjacent to each other as shown in FIG. 5. In this case, the centroid-to-centroid distance H satisfies 1.3L≤H≤2.7L with respect to the length L of the extension portions E1 and E2 such that the peak frequency can be positioned in the center portion of the frequency band determined depending on the dimensions of the non-conductive portions 22 and a sufficient amount of electromagnetic waves can transmit through the conductive member 11. In FIG. 5, the plurality of conductive wirings 21A are not shown to clearly show the relationship between the length of the extension portions E1 and E2 and the centroid-to-centroid distance H.

In addition, in the above description, each of the pair of extension portions E1 and E2 of the non-conductive portion 22 is disposed such that a center line CL2 along the long side of the rectangle is positioned on the same straight line with respect to conductive wiring 21A forming the mesh 14A. The center line CL2 does not need to be positioned on the same straight line with respect to the conductive wiring 21A.

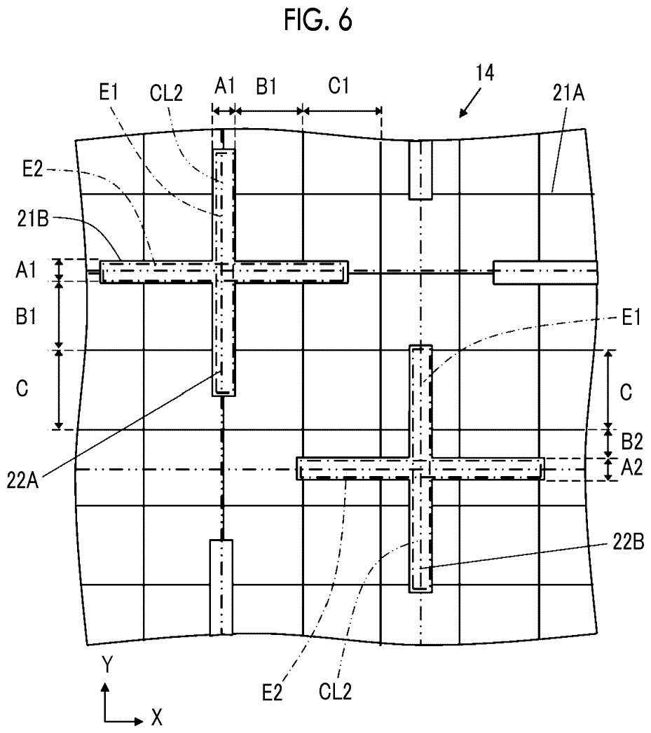

For example, as shown in FIG. 6, the mesh-shaped portion 14 can include: a non-conductive portion 22A where the center line CL2 is positioned on the same straight line with respect to the conductive wiring 21A; and a non-conductive portion 22B where the center line CL2 is not positioned on the same straight line with respect to the conductive wiring 21A. In the non-conductive portion 22A, a width A1 of the extension portions E1 and E2, a gap B1 in an orthogonal direction orthogonal to the extension direction of the extension portions E1 and E2 between the extension portions E1 and E2 and the conductive wirings 21A extending along the extension direction and adjacent to the extension portions E1 and E2 in the orthogonal direction, respectively, and a wiring pitch C of the plurality of conductive wirings 21A in the orthogonal direction satisfy A1<B1<C. In addition, in the non-conductive portion 22B, a width A2 of the extension portions E1 and E2, a gap B2 in an orthogonal direction orthogonal to the extension direction of the extension portions E1 and E2 between the extension portions E1 and E2 and the conductive wirings 21A extending along the extension direction and adjacent to the extension portions E1 and E2 in the orthogonal direction, respectively, and a wiring pitch C of the plurality of conductive wirings 21A in the orthogonal direction satisfy A2<B2<C.

Here, the extension direction of the extension portions E1 and E2 is the direction in which the extension portions E1 and E2 extend, which is the Y direction for the extension portion E1 and is the X direction for the extension portion E2. In addition, the orthogonal direction orthogonal to the extension direction is the X direction for the extension portion E1 and is the Y direction for the extension portion E2.

This way, the width A1, the gap B1, and the wiring pitch C satisfy A1<B1<C for the non-conductive portion 22A, and the width A2, the gap B2, and the wiring pitch C satisfy A2<B2<C for the non-conductive portion 22B. Therefore, a change in the dimensions of the width A1, the gap B1, and the wiring pitch C and a change in the dimensions of the width A2, the gap B2, and the wiring pitch C are inconspicuous to the observer who observes the mesh-shaped portion 14, and the conductive wirings 21A extending along the X direction and the Y direction and the conductive wiring 21B that trims the non-conductive portion 22 are not conspicuous.

However, a difference between the width A2 and the gap B2 in the non-conductive portion 22B where the center line CL2 is not positioned on the same straight line with respect to the conductive wiring 21A is less than a difference between the width A1 and the gap B1 in the non-conductive portion 22A where the center line CL2 is positioned on the same straight line with respect to the conductive wiring 21A, and the arrangement density of the conductive wirings 21A and 21B parallel to each other increases. Therefore, in the vicinity of the non-conductive portion 22B, the presence of the conductive wirings 21A and 21B is more conspicuous as compared to the vicinity of the non-conductive portion 22A. Therefore, in order to make the presence of the conductive wirings 21A and 21B inconspicuous, it is more preferable that the non-conductive portion 22A is disposed such that the center line CL2 is positioned on the same straight line with respect to the conductive wiring 21A.

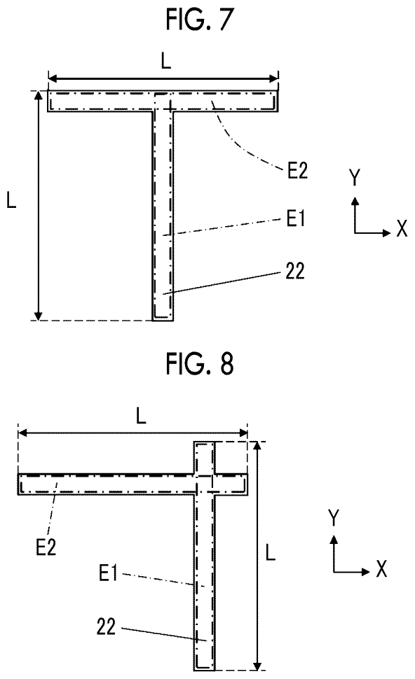

In addition, in the above description, the non-conductive portion 22 has a cross shape. As long as the non-conductive portion 22 includes the extension portion E1 or E2 extending along the conductive wiring 21A, the shape of the non-conductive portion 22 is not particularly limited. For example, as shown in FIG. 7, the non-conductive portion 22 can have a T-shape that is formed of the extension portion E1 extending along the Y direction and having the length L and the extension portion E2 extending along the X direction and having the length L. In addition, the non-conductive portion 22 can also have a shape shown in FIG. 8 that is formed of the extension portion E1 extending along the Y direction and having the length L and the extension portion E2 extending along the X direction and having the length L.

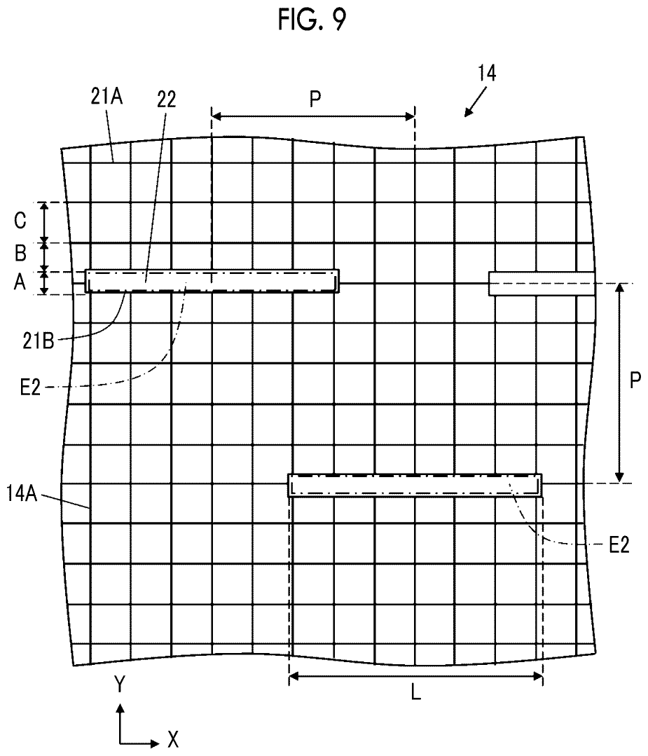

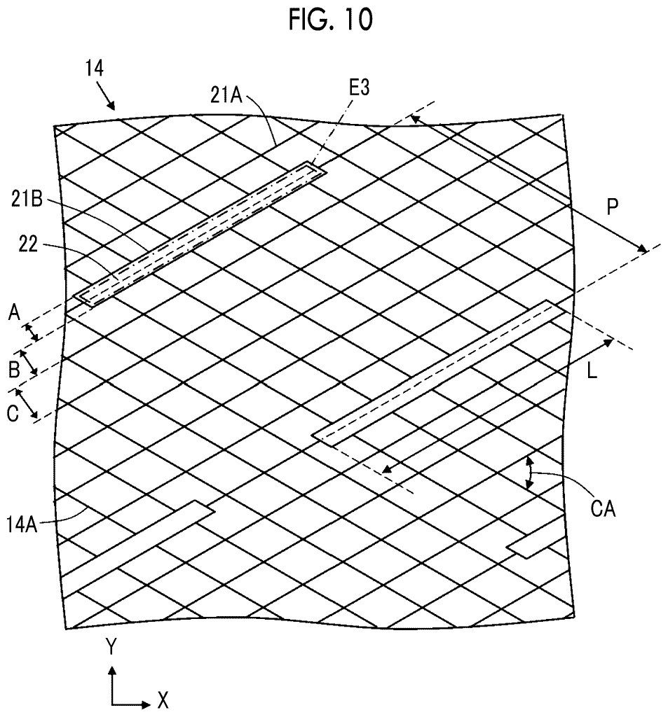

In addition, for example, as shown in FIG. 9, the non-conductive portion 22 can also have a shape of a rectangle that consists of only one extension portion E2 extending along the X direction and having the length L. Even in this case, as long as the width A, the gap B, and the wiring pitch C satisfy the relationship of A<B<C, the conductive wirings 21A and 21B can be made inconspicuous while simultaneously achieving a heat generation function and a function of allowing transmission of an electromagnetic wave in a specific frequency band.

In addition, in the above description, the plurality of conductive wirings 21A forming the mesh 14A are orthogonal to each other, that is, intersect each other at an intersecting angle of 90°. However, the intersecting angle of the plurality of conductive wirings 21A is not limited to 90°.

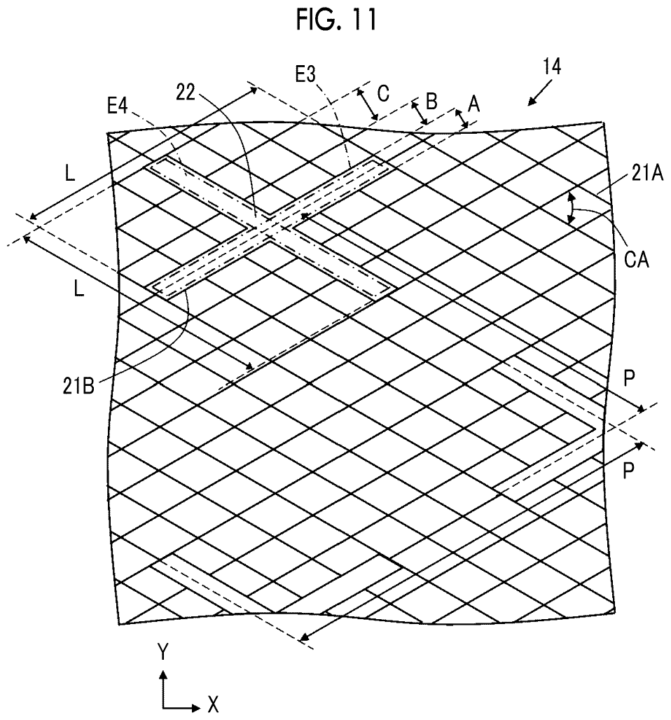

For example, as shown in FIG. 10, the plurality of conductive wirings 21A can also intersect each other at an intersecting angle CA different from 90°. In this case, the non-conductive portion 22 can also be configured with, for example, an extension portion E3 extending along one direction among the two directions in which the plurality of conductive wirings 21A extend. The conductive wiring 21B forming the non-conductive portion 22 has a pair of long sides extending along one direction and a pair of short sides extending along the other direction among the two directions in which the plurality of conductive wirings 21A extend. Therefore, the non-conductive portion 22 in FIG. 10 has a parallelogram shape. In addition, a width A of the extension portion E3 in an orthogonal direction orthogonal to a direction in which the pair of long side extend, a gap B between the extension portion E3 and the conductive wiring 21A extending along the direction in which the pair of long sides extend and adjacent to the extension portion E3 in the orthogonal direction, and a wiring pitch C of the plurality of conductive wirings 21A in the orthogonal direction satisfy a relational expression of A<B<C.

This way, even in a case where the plurality of conductive wirings 21A intersect each other at the intersecting angle CA different from 90° and the non-conductive portion 22 has a parallelogram shape shown in FIG. 10, the width A, the gap B, and the wiring pitch C satisfies the relational expression of A<B<C. Therefore, the conductive member 11 can make the conductive wirings 21A and 21B inconspicuous while simultaneously achieving a heat generation function and a function of allowing transmission of an electromagnetic wave in a specific frequency band.

In addition, even in a case where the plurality of conductive wirings 21A intersect each other at the intersecting angle CA different from 90°, the non-conductive portion 22 can also have, for example, a cross shape shown in FIG. 11. The non-conductive portion 22 shown in FIG. 11 includes the extension portion E3 extending along one direction and an extension portion E4 extending along the other direction among the two directions in which the plurality of conductive wirings 21A extend. The extension portion E3 has a parallelogram shape that consists of a pair of long sides extending along one direction and a pair of short sides extending along the other direction among the two directions in which the plurality of conductive wirings 21A extend. In addition, the extension portion E4 has a parallelogram shape that consists of a pair of long sides extending along the other direction and a pair of short side extending along the one direction.

Even in this case, the width A, the gap B, and the wiring pitch C of the extension portion E3 and the extension portion E4 satisfy the relational expression of A<B<C. Therefore, the conductive member 11 can make the conductive wirings 21A and 21B inconspicuous while simultaneously achieving a heat generation function and a function of allowing transmission of an electromagnetic wave in a specific frequency band.

In addition, the conductive layer 13 can also have a shape along a more complicated three-dimensional surface. Examples of the complicated three-dimensional shape include an emblem of an automobile, a radome of a radar, a front cover of a radar, a headlamp cover of an automobile, an antenna, and a reflector. By disposing the conductive member 11 according to the embodiment of the present invention along the three-dimensional shape, for example, the conductive member 11 can be disposed along an emblem of an automobile, and a radar can be mounted in the emblem.

In addition, in a case where the design of a member covered with the conductive member 11 is desired to be visible to an external observer, for example, in a case where the conductive member 11 is disposed along an emblem of an automobile, it is desirable that the conductive member 11 has transparency. In this case, in order to make the presence of the mesh-shaped portion 14 inconspicuous, the upper limit of the wiring pitch C of the plurality of conductive wirings 21A forming the mesh 14A is preferably 800.00 μm or less, more preferably 600.00 μm or less, and still more preferably 400.00 μm or less. In addition, the lower limit of the wiring pitch C is preferably 5.00 μm or more, more preferably 30.00 μm or more, and still more preferably 80.00 μm or more.

In addition, in order to for the conductive member 11 to have a visible light transmittance of 75.0% or more, an opening ratio of the mesh 14A is preferably 75% or more and more preferably 80% or more. Here, the opening ratio of the mesh 14A refers to the ratio of transmitting portions excluding the conductive wirings 21A to the region of the mesh 14A. That is, the opening ratio corresponds to a ratio of the total area of the plurality of opening portions J to the total area of the mesh 14A.

In addition, in the above description, the extension portions E1 and E2 forming the non-conductive portion 22 have a shape of a rectangle. However, the shape of the extension portions E1 and E2 is not particularly limited to rectangular shape as long as it is an elongated shape along one direction.

Hereinafter, each of the members forming the conductive member 11 according to the first embodiment will be described in detail.

### <Substrate>

The substrate 12 is not particularly limited as long as it has insulating properties and can support at least the conductive layer 13. However, it is preferable that the substrate 12 is transparent and is formed of a resin material.

Specific examples of the resin material forming the substrate 12 include polymethyl methacrylate (PMMA), acrylonitrile butadiene styrene (ABS), polyethylene terephthalate (PET), polycarbonate (PC), polycycloolefin, (meth)acryl, polyethylene naphthalate (PEN), polyethylene (PE), polypropylene (PP), polystyrene (PS), polyvinyl chloride (PVC), polyvinylidene chloride (PVDC), polyvinylidene difluoride (PVDF), polyarylate (PAR), polyethersulfone (PES), polymer acryl, a fluorene derivative, a crystalline cycloolefin polymer (COP), and triacetyl cellulose (TAC).

Here, from the viewpoints of the transparency and the durability of the substrate 12, it is preferable that the substrate 12 includes, as a major component, any one of a polymethyl methacrylate resin, a polycarbonate resin, an acrylonitrile/butadiene/styrene resin, or a polyethylene terephthalate resin. Here, the major component of the substrate 12 refers to a component of which the content is 80% or more with respect to the components of the substrate 12.

The visible light transmittance of the substrate 12 is preferably 85.0% to 100.0%.

In addition, the thickness of the substrate 12 is not particularly limited, and from the viewpoint of handleability or the like, is preferably 0.05 mm or more and 2.00 mm or less and more preferably 0.10 mm or more and 1.00 mm or less.

### <Primer Layer>

In order to strongly support a conductive layer 13, a primer layer may be provided between the substrate 12 and the conductive layer 13. The material of the primer layer is not limited as long as the conductive layer 13 can be strongly supported. In a case where the conductive layer 13 is formed of the plurality of conductive wirings 21, it is particularly preferable that the primer layer is formed of a urethane-based resin material.

### <Conductive Wiring>

The conductive wirings 21A and 21B are formed of a conductive material. As the conductive wirings 21A and 21B, a metal, a metal oxide, a carbon material, a conductive polymer, or the like can be used. For example, in a case where the conductive wiring 21 is formed of a metal, the kind of the metal is not particularly limited, and examples thereof include copper, silver, aluminum, chromium, lead, nickel, gold, tin, and zinc. From the viewpoint of conductivity, copper, silver, aluminum, or gold is preferable. Examples of a method forming the metallic conductive wiring 21 include a semi-additive method a fully additive method, a subtractive method, a silver halide method, printing of a metal-containing ink or a precursor thereof, an ink jet method, or a laser direct structuring method can be used, and a combination of the above methods can also be used. As the metal, a bulk material can be used, and nanowires or nanoparticles can also be used. In a case where the conductive wirings 21A and 21B are formed of a carbon material, the structure or the composition thereof as the conductive wirings 21A and 21B are not particularly limited, and carbon nanotubes, fullerene, carbon nanobuds, graphene, graphite, or the like can be used. In a case where the conductive wirings 21A and 21B are formed of a metal oxide, an indium tin oxide (ITO) can be used as the conductive wirings 21A and 21B. In a case where the conductive wirings 21A and 21B are formed of a conductive polymer, for example, poly(3,4-ethylenedioxythiophene) polystyrene sulfonate (PEDOT-PSS) can be used as the conductive wirings 21.

### EXAMPLES

Hereinafter, the present invention will be described in more detail based on the following examples. Materials, used amounts, ratios, treatment details, treatment procedures, and the like shown in the following examples can be appropriately changed within a range not departing from the scope of the present invention. Accordingly, the scope of the present invention is not limited to the following examples.

### Example 1

### (Preparation of Substrate)

A polycarbonate resin film (PANLITE PC-2151, manufactured by Teijin Ltd.) having a thickness of 250.0 μm was prepared as a substrate.

### (Preparation of Composition for Forming Primer Layer)

The following components were mixed to obtain a composition for forming a primer layer.

| | |
|---|---|
| Z913-3 (manufactured by Aica Kogyo Co., Ltd.) | 33 parts by mass |
| IPA (isopropyl alcohol) | 67 parts by mass |

### (Formation of Primer Layer)

The obtained composition for forming a primer layer was applied using a bar coating method to the substrate such that an average dry film thickness was 1.0 μm, and was dried at 80° C. for 1 minute. Next, the formed layer of the composition for forming a primer layer was irradiated with ultraviolet (UV) rays at an irradiation dose of 1000 mJ to form a primer layer having a thickness of 0.8 μm.

### (Preparation of Composition for Forming Plated Layer Precursor Layer)

The following components were mixed to obtain a composition for forming a plated layer precursor layer.

| | | |
|---|---|---|
| IPA (isopropyl alcohol | 38.00 | parts by mass |
| Polybutadiene maleic acid | 4.00 | parts by mass |
| FOM-03008 (manufactured by | 1.00 | part by mass |
| Fujifilm Wako Pure Chemical Corporation) | | |
| IRGACURE OXE02 (manufactured by | 0.05 | parts by mass |
| BASF SE, ClogP = 6.55) | | |

FOM-03008 includes a compound represented by the following formula as a major component.

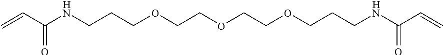 [SMILES: C=CC(=O)NCCCOCCOCCOCCCNC(=O)C=C]

(Preparation of Substrate with Plated Layer Precursor Layer)

The obtained composition for forming a plated layer precursor layer was applied using a bar coating method to the primer layer such that the film thickness was 0.2 μm, and was dried in an atmosphere of 120° C. for 1 minute. Next, by bonding a polypropylene film having a thickness of 12.0 μm to the composition for forming a plated layer precursor layer, a substrate with the plated layer precursor layer was prepared.

(Preparation of Substrate with Plated Layer)

A quartz glass film mask on which an exposure pattern corresponding to the mesh-shaped portion 14 and the pair of electrode pads 15 shown in FIG. 10 was formed was prepared. The film mask was attached to the plated layer precursor layer side of the substrate with the plated layer precursor layer, and UV irradiation (energy amount: 200 mJ/cm², wavelength: 365 nm) was performed through the film mask. Next, the substrate with the plated layer precursor layer irradiated with ultraviolet light was developed by pure showering for 5 minutes. As a result, the substrate with the patterned plated layer was prepared.

### (Formation of Conductive Film)

The substrate with the patterned plated layer was dipped in a 1 mass % sodium bicarbonate aqueous solution at 35° C. for 5 minutes. Next, the substrate with the patterned plated layer was dipped in a palladium catalyst-added solution RONAMERSE SMT (manufactured by Rohm and Haas Electronic Materials LLC) at 55° C. for 5 minutes. The substrate with the plated layer was cleaned with water, was dipped in CIRCUPOSIT 6540 (manufactured by Rohm and Haas Electronic Materials LLC) at 35° C. for 5 minutes, and subsequently was cleaned with water again. Further, the substrate with the plated layer was dipped in CIRCUPOSIT 4500 (manufactured by Rohm and Haas Electronic Materials LLC) at 45° C. for 20 minutes and was cleaned with water to form a conductive film on the plated layer. As a result, a conductive member according to Example 1 including, on the substrate, the mesh-shaped portion 14 where the plurality of non-conductive portions 22 having a parallelogram shape shown in FIG. 10 were disposed and a copper conductive layer where the pair of electrode pads 15 shown in FIG. 2 were provided was obtained.

In the conductive member according to Example 1, the intersecting angle CA of the plurality of conductive wirings 21A forming the mesh 14A was 60°. In addition, the length L of the extension portion E3 in the non-conductive portion 22 was 1300 μm, the centroid-to-centroid distance H between the two non-conductive portions 22 adjacent to each other was 2000 μm, the width A of the extension portion E3 was 120 μm, the gap B in the orthogonal direction between the extension portion E3 and the conductive wiring 21A extending along the direction in which the pair of long sides of the extension portion E3 extended and adjacent to the extension portion E3 in the orthogonal direction orthogonal to the extension direction was 150 μm, and the wiring pitch C of the plurality of conductive wirings 21 was 210 μm. A ratio H/L of the centroid-to-centroid distance H to the length L of the extension portion E3 was 2000/1300≈1.54. In addition, a ratio A/B of the width A to the gap B was 120/150=0.80, and a ratio B/C of the gap B to the wiring pitch C was 150/210≈0.71. In addition, a ratio A/L of the width A to the length L of the extension portion E3 was 120/1300≈0.09.

### Example 2

A conductive member according to Example 2 was prepared using the same method as that of Example 1, except that a film mask including the mesh-shaped portion 14 shown in FIG. 11 instead of the mesh-shaped portion 14 shown in FIG. 10 was used.

In the conductive member according to Example 2, the intersecting angle CA of the plurality of conductive wirings 21A forming the mesh 14A was 60°. In addition, the length L of the extension portions E3 and E4 in the non-conductive portion 22 was 1300 μm, the centroid-to-centroid distance H between the two non-conductive portions 22 adjacent to each other was 2000 μm, the width A of the extension portions E3 and E4 was 120 μm, the gap B in the orthogonal direction between the extension portion E3 and the conductive wiring 21A extending along the direction in which the pair of long sides of the extension portion E3 extended and adjacent to the extension portion E3 in the orthogonal direction orthogonal to the extension direction was 150 μm, and the wiring pitch C of the plurality of conductive wirings 21 was 210 μm. In addition, the gap B in the orthogonal direction between the extension portion E4 and the conductive wiring 21A extending along the direction in which the pair of long sides of the extension portion E4 extended and adjacent to the extension portion E4 in the orthogonal direction orthogonal to the extension direction was 150 μm.

In addition, a ratio H/L of the centroid-to-centroid distance H to the length L of the extension portions E3 and E4 was 2000/1300≈1.54. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E3 and E4 was 120/1300≈0.09.

### Example 3

A conductive member according to Example 3 was prepared using the same method as that of Example 1, except that a film mask including the mesh-shaped portion 14 shown in FIGS. 2 and 4 instead of the mesh-shaped portion 14 shown in FIG. 10 was used.

In the conductive member according to Example 3, the plurality of conductive wirings 21A forming the mesh 14A were orthogonal to each other (the intersecting angle CA was) 90°. In addition, the length L of the extension portions E1 and E2 in the non-conductive portion 22 was 1300 μm, the centroid-to-centroid distance H between the two non-conductive portions 22 adjacent to each other was 2000 μm, the width A of the extension portions E1 and E2 was 120 μm, the gap B in the orthogonal direction between the extension portion E1 and the conductive wiring 21A extending along the direction in which the pair of long sides of the extension portion E1 extended and adjacent to the extension portion E1 in the orthogonal direction orthogonal to the extension direction was 150 μm, and the wiring pitch C of the plurality of conductive wirings 21 was 210 μm. In addition, the gap B in the orthogonal direction between the extension portion E2 and the conductive wiring 21A extending along the direction in which the pair of long sides of the extension portion E2 extended and adjacent to the extension portion E2 in the orthogonal direction orthogonal to the extension direction was 150 μm.

In addition, a ratio H/L of the centroid-to-centroid distance H to the length L of the extension portions E1 and E2 was 2000/1300≈1.54. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/1300≈0.09.

### Example 4

A conductive member according to Example 4 was prepared using the same method as that of the conductive member according to Example 3, except that the gap B was changed to 240 μm and the wiring pitch C was changed to 300 μm. In the conductive member according to Example 4, a ratio H/L of the centroid-to-centroid distance H to the length L of the extension portions E1 and E2 was 2000/1300≈1.54. In addition, a ratio A/B of the width A to the gap B was 120/240=0.50, and a ratio B/C of the gap B to the wiring pitch C was 240/300≈0.80. In addition, a ratio A/L of the width A to the length L of the extension portions E1 and E2 was 120/1300≈0.09.

### Example 5

A conductive member according to Example 5 was prepared using the same method as that of the conductive member according to Example 3, except that the gap B was changed to 360 μm and the wiring pitch C was changed to 420 μm. In the conductive member according to Example 5, a ratio H/L of the centroid-to-centroid distance H to the length L of the extension portions E1 and E2 was 2000/1300≈1.54. In addition, a ratio A/B of the width A to the gap B was 120/360=0.33, and a ratio B/C of the gap B to the wiring pitch C was 360/420≈0.86. In addition, a ratio A/L of the width A to the length L of the extension portions E1 and E2 was 120/1300≈0.09.

### Example 6

A conductive member according to Example 6 was prepared using the same method as that of the conductive member according to Example 3, except that the wiring pitch C was changed to 420 μm. In the conductive member according to Example 6, a ratio H/L of the centroid-to-centroid distance H to the length L of the extension portions E1 and E2 was 2000/1300≈1.54. In addition, a ratio A/B of the width A to the gap B was 120/150=0.80, and a ratio B/C of the gap B to the wiring pitch C was 150/420≈0.36. In addition, a ratio A/L of the width A to the length L of the extension portions E1 and E2 was 120/1300≈0.09.

### Example 7

A conductive member according to Example 7 was prepared using the same method as that of the conductive member according to Example 3, except that the length L of the extension portions E1 and E2 was changed to 700 μm. In the conductive member according to Example 7, a ratio H/L of the centroid-to-centroid distance H to the length L of the extension portions E1 and E2 was 2000/700≈2.86. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/700≈0.17.

### Example 8

A conductive member according to Example 8 was prepared using the same method as that of the conductive member according to Example 3, except that the length L of the extension portions E1 and E2 was changed to 980 μm. In the conductive member according to Example 8, a ratio H/L of the centroid-to-centroid distance H to the length L of the extension portions E1 and E2 was 2000/980≈2.04. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/980≈0.12.

### Example 9

A conductive member according to Example 9 was prepared using the same method as that of the conductive member according to Example 3, except that the length L of the extension portions E1 and E2 was changed to 1960 μm. In the conductive member according to Example 9, a ratio H/L of the centroid-to-centroid distance H to the length L of the extension portions E1 and E2 was 2000/1960≈1.02. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/1960≈0.06.

### Example 10

A conductive member according to Example 10 was prepared using the same method as that of the conductive member according to Example 3, except that the length L of the extension portions E1 and E2 was changed to 2200 μm. In the conductive member according to Example 10, a ratio H/L of the centroid-to-centroid distance H to the length L of the extension portions E1 and E2 was 2000/2200≈0.91. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/2200≈0.05.

### Example 11

A conductive member according to Example 11 was prepared using the same method as that of the conductive member according to Example 3, except that the centroid-to-centroid distance H of the two non-conductive portions 22 adjacent to each other was changed to 1560 μm. In the conductive member according to Example 11, a ratio H/L of the centroid-to-centroid distance H to the length L of the extension portions E1 and E2 was 1560/1300≈1.20. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/1300≈0.09.

### Example 12

A conductive member according to Example 12 was prepared using the same method as that of the conductive member according to Example 3, except that the centroid-to-centroid distance H of the two non-conductive portions 22 adjacent to each other was changed to 1700 μm. In the conductive member according to Example 12, a ratio H/L of the centroid-to-centroid distance H to the length L of the extension portions E1 and E2 was 1700/1300≈1.31. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/1300≈0.09.

### Example 13

A conductive member according to Example 13 was prepared using the same method as that of the conductive member according to Example 3, except that the centroid-to-centroid distance H of the two non-conductive portions 22 adjacent to each other was changed to 3400 μm. In the conductive member according to Example 13, a ratio H/L of the centroid-to-centroid distance H to the length L of the extension portions E1 and E2 was 3400/1300≈2.62. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/1300=0.09.

### Example 14

A conductive member according to Example 14 was prepared using the same method as that of the conductive member according to Example 3, except that the centroid-to-centroid distance H of the two non-conductive portions 22 adjacent to each other was changed to 3900 μm. In the conductive member according to Example 14, a ratio H/L of the centroid-to-centroid distance H to the length L of the extension portions E1 and E2 was 3900/1300≈3.00. In addition, a ratio A/B of the width A to the gap B was 120/150=0.80, and a ratio B/C of the gap B to the wiring pitch C was 150/210≈0.71. In addition, a ratio A/L of the width A to the length L of the extension portions E1 and E2 was 120/1300≈0.09.

### Example 15

A conductive member according to Example 15 was prepared using the same method as that of the conductive member according to Example 3, except that the width A of the extension portions E1 and E2 was changed to 20 μm, the gap B was changed to 60 μm, and the wiring pitch C was changed to 100 μm. In the conductive member according to Example 15, a ratio H/L of the centroid-to-centroid distance H to the length L of the extension portions E1 and E2 was 2000/1300≈1.54. In addition, a ratio A/B of the width A to the gap B was 20/60=0.33, and a ratio B/C of the gap B to the wiring pitch C was 60/100≈0.60. In addition, a ratio A/L of the width A to the length L of the extension portions E1 and E2 was 20/1300≈0.02.

### Example 16

A conductive member according to Example 16 was prepared using the same method as that of the conductive member according to Example 3, except that the width A of the extension portions E1 and E2 was changed to 50 μm, the gap B was changed to 100 μm, and the wiring pitch C was changed to 125 μm. In the conductive member according to Example 16, a ratio H/L of the centroid-to-centroid distance H to the length L of the extension portions E1 and E2 was 2000/1300≈1.54. In addition, a ratio A/B of the width A to the gap B was 50/100=0.50, and a ratio B/C of the gap B to the wiring pitch C was 100/125≈0.80. In addition, a ratio A/L of the width A to the length L of the extension portions E1 and E2 was 50/1300≈0.04.

### Example 17

A conductive member according to Example 17 was prepared using the same method as that of the conductive member according to Example 3, except that the width A of the extension portions E1 and E2 was changed to 400 μm, the gap B was changed to 450 μm, and the wiring pitch C was changed to 650 μm. In the conductive member according to Example 17, a ratio H/L of the centroid-to-centroid distance H to the length L of the extension portions E1 and E2 was 2000/1300≈1.54. In addition, a ratio A/B of the width A to the gap B was 400/450=0.89, and a ratio B/C of the gap B to the wiring pitch C was 450/650≈0.69. In addition, a ratio A/L of the width A to the length L of the extension portions E1 and E2 was 400/1300≈0.31.

### Example 18

A conductive member according to Example 18 was prepared using the same method as that of the conductive member according to Example 3, except that the width A of the extension portions E1 and E2 was changed to 500 μm, the gap B was changed to 550 μm, and the wiring pitch C was changed to 800 μm. In the conductive member according to Example 18, a ratio H/L of the centroid-to-centroid distance H to the length L of the extension portions E1 and E2 was 2000/1300≈1.54. In addition, a ratio A/B of the width A to the gap B was 500/550=0.91, and a ratio B/C of the gap B to the wiring pitch C was 550/800≈0.69. In addition, a ratio A/L of the width A to the length L of the extension portions E1 and E2 was 500/1300≈0.38.

### Comparative Example 1

A conductive member according to Comparative Example 1 was prepared using the same method as that of the conductive member according to Example 3, except that the width A of the extension portions E1 and E2 was changed to 120 μm, the gap B was changed to 40 μm, and the wiring pitch C was changed to 100 μm. This way, in Comparative Example 1, a relationship of the width A, the gap B, and the wiring pitch C was B<C<A.

### Comparative Example 2

A conductive member according to Comparative Example 2 was prepared using the same method as that of the conductive member according to Example 3, except that a film mask where an exposure pattern corresponding to the mesh-shaped portion 14 including a non-conductive portion such as the non-conductive portion 22B of FIG. 6 instead of the mesh-shaped portion 14 shown in FIGS. 2 and 4 was formed was used, the non-conductive portion having a configuration where the center line CL2 of the extension portions E1 and E2 was not positioned on the same straight line with respect to the conductive wiring 21A.

In the conductive member according to Comparative Example 2, the width A of the extension portions E1 and E2 was changed to 120 μm, the gap B was changed to 90 μm, and the wiring pitch C was changed to 300 μm. In addition, a ratio H/L of the centroid-to-centroid distance H to the length L of the extension portions E1 and E2 was 2000/1300≈1.54. In addition, a ratio A/B of the width A to the gap B was 120/90=1.33, and a ratio B/C of the gap B to the wiring pitch C was 120/300≈0.40. In addition, a ratio A/L of the width A to the length L of the extension portions E1 and E2 was 120/1300≈0.09.

For the conductive members according to Examples 1 to 18 and Comparative Examples 1 and 2 obtained as described above, the following evaluations were performed.

### (Visibility Evaluation)

In a state where 10 observers were disposed at a position spaced from the conductive member by 1 m and the conductive member was held up to a fluorescent lamp, each of the observers observed the conductive member to evaluate whether or not the conductive wiring and the non-conductive portion were visible. A case where the number of persons who observed the conductive wiring and the non-conductive portion was less than 2 was evaluated as A, a case where the number of persons was 2 or more and less than 5 was evaluated as B, and a case where the number of persons was 5 or more was evaluated as C. The evaluation A represents that the conductive wiring and the non-conductive portion are not substantially visible, that is, the conductive member has excellent visibility. The evaluation B represents that the conductive member has visibility that has no problem in practice. The evaluation C represents that the conductive member has visibility that has a problem in practice.

### (Electromagnetic Wave Transmittance Evaluation)

The transmittance of the conductive member with respect to a millimeter wave in a specific wavelength was measured using a millimeter wave network analyzer (N5290A, manufactured by Keysight Technologies Inc.). In this case, first the conductive member was bonded to a stainless steel plate having a thickness of 2 mm having a hole with a diameter of 80 mm. In addition, the millimeter wave network analyzer was provided such that two ports faced each other. In addition, the conductive member bonded to the stainless steel plate was disposed such that the hole having a diameter of 80 mm of the stainless steel plate was positioned at an intermediate point between the two ports and the flat surface of the conductive member was perpendicular to a line segment connecting the two ports. In this state, the transmittance of the conductive member with respect to a millimeter wave in 76.5 GHz was measured. Assuming that the transmittance measured without disposing the conductive member between the two ports was 0 dB, the transmittance of the conductive member was calculated. A case where the measured transmittance was-1.0 dB or more was evaluated as A, and a case where the measured transmittance was less than-1.0 dB was evaluated as B. The evaluation B has no problem in practice but is poorer than the evaluation A.

Table 1 below shows the results of the visibility evaluation and the electromagnetic wave transmittance evaluation for Examples 1 to 18 and Comparative Examples 1 and 2.

TABLE 1

| | Intersecting | | Length L | | | | | | Electromagnetic |
|---|---|---|---|---|---|---|---|---|---|
| | Angle of | Shape of | (μm) of | | Width | Gap | Wiring | | Wave |
| | Conductive | Non-Conductive | Extension | Centroid-to-Centroid | A | B | Pitch | Visibility | Transmittance |
| | Wirings | Portion | Portion | Distance H (μm) | (μm) | (μm) | C (μm) | Evaluation | Evaluation |
| Example 1 | 60° | Parallelogram | 1300 | 2000 | 120 | 150 | 210 | A | A |
| | | Shape | | | | | | | |
| Example 2 | 60° | Cross Shape | 1300 | 2000 | 120 | 150 | 210 | A | A |
| Example 3 | 90° | Cross Shape | 1300 | 2000 | 120 | 150 | 210 | A | A |
| Example 4 | 90° | Cross Shape | 1300 | 2000 | 120 | 240 | 300 | A | A |
| Example 5 | 90° | Cross Shape | 1300 | 2000 | 120 | 360 | 420 | A | A |
| Example 6 | 90° | Cross Shape | 1300 | 2000 | 120 | 150 | 420 | B | A |
| Example 7 | 90° | Cross Shape | 700 | 2000 | 120 | 150 | 210 | A | B |
| Example 8 | 90° | Cross Shape | 980 | 2000 | 120 | 150 | 210 | A | A |
| Example 9 | 90° | Cross Shape | 1960 | 2000 | 120 | 150 | 210 | A | A |
| Example 10 | 90° | Cross Shape | 2200 | 2000 | 120 | 150 | 210 | A | B |
| Example 11 | 90° | Cross Shape | 1300 | 1560 | 120 | 150 | 210 | A | B |
| Example 12 | 90° | Cross Shape | 1300 | 1700 | 120 | 150 | 210 | A | A |
| Example 13 | 90° | Cross Shape | 1300 | 3400 | 120 | 150 | 210 | A | A |
| Example 14 | 90° | Cross Shape | 1300 | 3900 | 120 | 150 | 210 | A | B |
| Example 15 | 90° | Cross Shape | 1300 | 2000 | 20 | 60 | 100 | A | B |
| Example 16 | 90° | Cross Shape | 1300 | 2000 | 50 | 100 | 125 | A | A |
| Example 17 | 90° | Cross Shape | 1300 | 2000 | 400 | 450 | 650 | A | A |
| Example 18 | 90° | Cross Shape | 1300 | 2000 | 500 | 550 | 800 | A | A |
| Comparative | 90° | Cross Shape | 1300 | 2000 | 120 | 40 | 100 | C | A |
| Example 1 | | | | | | | | | |
| Comparative | 90° | Cross Shape | 1300 | 2000 | 120 | 90 | 300 | C | A |
| Example 2 | | | | | | | | | |

As shown in Table 1, it can be seen that, in the conductive members according to Examples 1 to 18, since the width A, the gap B, and the wiring pitch C satisfied the relational expression of A<B<C, all of the results of the visibility evaluation were B or higher, and the visibility had at least no problem in practice while having a function of selectively allowing transmission of a specific electromagnetic wave.

On the other hand, it can be seen that, in Comparative Examples 1 and 2, since the width A, the gap B, and the wiring pitch C satisfied a relational expression of B<A<C and did not satisfy a relational expression of A<B<C, the evaluation results of the visibility were all C and the conductive wirings 21A and 21B were conspicuous.

Hereinafter, the evaluation results of Examples 1 to 18 were compared.

In addition, in Examples 1 to 5 and 7 to 18, the width A, since the gap B, and the wiring pitch C satisfied a relational expression of A>0.3B>0.16C, the evaluation results of the visibility were all A. In Example 6, the width A and the gap B satisfied A>0.3B, whereas the gap B 0.3 was 45.0 and the wiring pitch C 0.16 was 67.2 such that 0.3B>0.16C was not satisfied. Therefore, it is considered that the width A and the gap B that were relatively narrow were continuous, and the presence of the non-conductive portion 22 was relatively easily conspicuous.

In Examples 7 to 10, only the length L of the extension portions E1 and E2 changed. Among Examples 7 to 10, the evaluation results of the electromagnetic wave transmittance of Examples 8 and 9 were A, but the evaluation results of the electromagnetic wave transmittance of Examples 7 and 10 were B. A ratio L/K of the length L of the extension portions E1 and E2 to the wavelength K of an electromagnetic wave of 76.5 GHz used in the electromagnetic wave transmittance evaluation was about 700 μm/3920 μm≈0.18 in Example 7, was about 980 μm/3920 μm≈0.25 in Example 8, was about 1960 μm/3920 μm≈0.50 in Example 9, and was about 2200 μm/3960 μm≈0.56 in Example 10. Therefore, among Examples 7 to 10, Examples 8 and 9 satisfied a relational expression of K/4≤L≤K/2. It can be seen from the result that, by satisfying a relational expression of K/4≤L≤K/2, an electromagnetic wave having the wavelength K as a central wavelength can be made sufficiently transmit through the conductive member.

In Examples 11 to 14, only the centroid-to-centroid distance H changed. Among Examples 11 to 14, the evaluation results of the electromagnetic wave transmittance of Examples 12 and 13 were A, but the evaluation results of the electromagnetic wave transmittance of Examples 11 and 14 were B. The value of the ratio H/L was about 1.20 in Example 11, was about 1.31 in Example 12, was about 2.62 in Example 13, and was about 3.00 in Example 14. In Examples 12 and 13, the length L of the extension portions E1 and E2 and the centroid-to-centroid distance H satisfied 1.3L<H≤2.7L. Therefore, it is considered that, in Example 12, the peak frequency of the electromagnetic wave transmitted through the conductive member was positioned in the vicinity of the center of the frequency band determined depending on the dimensions of the non-conductive portion 22, and a sufficient amount of the electromagnetic wave was able to transmit through the conductive member.

In Examples 15 to 18, only the width A of the extension portions E1 and E2, the gap B, and the wiring pitch C changed. Among Examples 15 to 18, the evaluation results of the electromagnetic wave transmittance of Examples 16 to 18 were A, but the evaluation result of the electromagnetic wave transmittance of Example 15 was B. The value of the ratio A/L was about 0.02 in Example 15, was about 0.04 in Example 16, was about 0.31 in Example 17, and was about 0.38 in Example 18. Therefore, in Examples 16 to 18, a relational expression of 0.04L≤A≤0.3L was satisfied, whereas this relational expression was not satisfied in Example 15. Therefore, it is considered that the amount of the electromagnetic wave transmitted was relatively large in Examples 16 to 18, and the amount of the electromagnetic wave transmitted was relatively small in Example 15.

Basically, the present invention is configured as described above. Hereinabove, the conductive member according to the embodiment of the present invention has been described in detail. However, the present invention is not limited to the above-described examples, and various improvements or modifications can be made within a range not departing from the scope of the present invention.

### EXPLANATION OF REFERENCES

12: substrate
13: conductive layer
14: mesh-shaped portion
14A: mesh
15: electrode pad
21A, 21B: conductive wiring
22, 22A, 22B: non-conductive portion
A, A1, A2: width
B, B1, B2: gap
C: wiring pitch
CA: intersecting angle
CL1, CL2: center line
E1, E2, E3, E4: extension portion
G: centroid
H: centroid-to-centroid distance
J: opening portion
L: length
P: arrangement pitch
W: line width

What is claimed is:

1. A conductive member comprising:
a substrate; and
a mesh-shaped portion that includes a plurality of meshes formed of a plurality of conductive wirings disposed on the substrate and extending along two directions intersecting each other,
wherein the plurality of conductive wirings are arranged at regular intervals by respectively determined wiring pitches in two arrangement directions orthogonal to the two directions, respectively,
the mesh-shaped portion includes a plurality of non-conductive portions that are arranged to form a regular repeating pattern and each of which is trimmed by the continuous conductive wiring,
the non-conductive portion includes at least one extension portion,
the extension portion extends along one direction among the two directions, and
a width A of the extension portion in an orthogonal direction orthogonal to the one direction, a gap B in the orthogonal direction between the extension portion and the conductive wiring that extends along the one direction and is adjacent to the extension portion in the orthogonal direction, and the wiring pitch C of the plurality of conductive wirings in the orthogonal direction satisfy a relational expression of A<B<C.

2. The conductive member according to claim 1,
wherein the width A, the gap B, and the wiring pitch C satisfy a relational expression of A>0.3B>0.16C.

3. The conductive member according to claim 1,
wherein the two directions are orthogonal to each other,
the non-conductive portion includes a pair of the extension portions extending along the two directions, respectively, and intersecting each other, and
each of the pair of extension portions satisfies the relational expression.

4. The conductive member according to claim 2,
wherein the two directions are orthogonal to each other,
the non-conductive portion includes a pair of the extension portions extending along the two directions, respectively, and intersecting each other, and
each of the pair of extension portions satisfies the relational expression.

5. The conductive member according to claim 3,
wherein the non-conductive portion has a shape where a pair of rectangles having the same shape and size are orthogonal to each other.

6. The conductive member according to claim 1,
wherein the extension portion has a shape of a rectangle having a long side along the one direction.

7. The conductive member according to claim 2,
wherein the extension portion has a shape of a rectangle having a long side along the one direction.

8. The conductive member according to claim 6,
wherein the extension portion is disposed such that a center line along the long side of the rectangle is positioned on the same straight line with respect to the conductive wiring forming the mesh.

9. The conductive member according to claim 1,
wherein a length L of the extension portion in the one direction satisfies K/4≤L≤K/2 with respect to a wavelength K of an electromagnetic wave transmitted through the non-conductive portion.

10. The conductive member according to claim 2,
wherein a length L of the extension portion in the one direction satisfies K/4≤L≤K/2 with respect to a wavelength K of an electromagnetic wave transmitted through the non-conductive portion.

11. The conductive member according to claim 3,
wherein a length L of the extension portion in the one direction satisfies K/4≤L≤K/2 with respect to a wavelength K of an electromagnetic wave transmitted through the non-conductive portion.

12. The conductive member according to claim 5,
wherein a length L of the extension portion in the one direction satisfies K/4≤L≤ K/2 with respect to a wavelength K of an electromagnetic wave transmitted through the non-conductive portion.

13. The conductive member according to claim 1,
wherein the width A of the extension portion satisfies 0.04L≤A≤0.3L with respect to a length L of the extension portion in the one direction.

14. The conductive member according to claim 2,
wherein the width A of the extension portion satisfies 0.04L≤A≤0.3L with respect to a length L of the extension portion in the one direction.

15. The conductive member according to claim 3,
wherein the width A of the extension portion satisfies 0.04L≤A≤0.3L with respect to a length L of the extension portion in the one direction.

16. The conductive member according to claim 1,
wherein a centroid-to-centroid distance H of the two non-conductive portions adjacent to each other satisfies 1.3L≤H≤2.7L with respect to a length L of the extension portion in the one direction.

17. The conductive member according to claim 2,
wherein a centroid-to-centroid distance H of the two non-conductive portions adjacent to each other satisfies 1.3L≤H≤2.7L with respect to a length L of the extension portion in the one direction.

18. The conductive member according to claim 3,
wherein a centroid-to-centroid distance H of the two non-conductive portions adjacent to each other satisfies 1.3L≤H≤2.7L with respect to a length L of the extension portion in the one direction.

19. A heater comprising:
the conductive member according to claim 1.

20. A light control cell comprising:
the conductive member according to claim 1.
